(19) United States
(12) Patent Application Publication
(10) Pub. No.: US 2008/0265905 A1
(43) Pub. Date: Oct. 30, 2008

(54) SYSTEM AND METHOD FOR DETECTION OF ENVIRONMENTALLY-INDUCED DAMAGE OF CONDUCTIVE ELEMENTS IN A CIRCUIT BOARD

(75) Inventors: Srinivasan Kadathur, Austin, TX (US); Barry Kahr, Austin, TX (US)

Correspondence Address: BAKER BOTTS, LLP, 910 LOUISIANA, HOUSTON, TX, 77002-4995, US

(73) Assignee: DELL PRODUCTS L.P., Round Rock, TX (US)

(21) Appl. No.: 11/741,508

(22) Filed: Apr. 27, 2007

(51) Int. Cl. G01R 31/02

(52) U.S. Cl. 324/537

(57) ABSTRACT

A system and method for detection of environmentally-induced damage of conductive elements in a circuit board are disclosed. A system may include a test module and a detection module operably connected to the test module. The test module may comprise at least one conductive element. The detection module may be operable to detect a change in at least one electrical property associated with the at least one of conductive element, wherein the change occurs at least in part as a result of environmentally-induced damage to the at least one conductive element.

### TECHNICAL FIELD

The present disclosure relates in general to the detection of damage in a circuit board, and more particularly to a system and method for detection of environmentally-induced damage of conductive elements in a circuit board.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include one or more circuit boards operable to mechanically support and electrically connect electronic components making up the information handling system. For example, circuit boards may be used as part of motherboards, memories, storage devices, storage device controllers, peripherals, peripheral cards, network interface cards, and/or other electronic components.

While circuit boards are generally highly reliable, circuit boards may include conductive elements that may experience damage to any number of environmental conditions, such as, for example, copper, silver, aluminum, lead, nickel, other metals, and/or other conductive materials making up the various pads and/or traces of a circuit board. For example, conductive elements may experience corrosion, tarnishing, oxidation or other damage from exposure to air ambient to the conductive elements. Such corrosion, tarnishing and oxidation may be further exacerbated in many industrial and manufacturing applications, wherein conductive elements may be exposed to one or more airborne caustic substances (e.g., sulphur, ammonia, hydrogen chloride, chlorine and methylamine) that expedite and/or enhance damage. Damage to conductive elements may also be enhanced by exposure to heat and/or many other environmental conditions. Furthermore, damage to conductive elements may be caused by electromigration and/or similar phenomena.

In certain instances, environmentally-induced damage to conductive elements may lead to malfunction and/or inoperability of a circuit board. For example, environmentally-induced damage may cause conductive elements of a circuit board (e.g., conductive pads and/or traces) designed to be electrically isolated from another to develop leakage currents between the conductive elements that may lead to malfunction and/or inoperability. As another example, environmentally-induced damage may also cause conductive elements that are designed to be electrically isolated from one other to form a “bridge” or a “short” that may lead to malfunction and/or inoperability. In other instances, environmentally-induced damage may cause a “break” in a conductive element, thereby creating an “open” that may lead to malfunction and/or inoperability.

However, occurrence of environmentally-induced damage may be difficult to detect using conventional methods. Accordingly, a circuit board that has suffered environmentally-induced damage may experience a malfunction, but because of the difficulty of detecting environmentally-induced damage, the cause of such a malfunction may be difficult to isolate. In many instances, such malfunctions often cannot be reproduced or are intermittent, further adding to the difficulty in isolating the cause of the malfunction.

In certain instances, when a circuit board malfunction cannot be reproduced, the circuit board may be resold or redistributed for further use. Thus, some circuit boards may be redistributed despite that such boards may suffer from a degree of environmentally-induced damage that may again lead to malfunction and/or inoperability.

Accordingly, a need has arisen for systems and methods that provide for detection of environmentally-induced damage to conductive elements of a circuit board.

### SUMMARY

In accordance with the teachings of the present disclosure, disadvantages and problems associated with the detection of environmentally-induced damage of conductive elements in a circuit board may be substantially reduced or eliminated. For example, the systems and methods disclosed herein may be technically advantageous because they may provide for the on-board detection of environmentally-induced damage prior to malfunction of a circuit board. In a particular embodiment, environmentally-induced damage of a test module disposed in a circuit board may induce a change in one or more electrical properties of the test module, and such change in the one or more electrical properties may be detected to indicate the presence of environmentally-induced damage.

In accordance with one embodiment of the present disclosure, a system for detection of environmentally-induced damage of conductive elements in a circuit board may include a test module and a detection module operably connected to the test module. The test module may comprise at least one conductive element. The detection module may be operable to detect a change in at least one electrical property associated with the at least one conductive element, wherein the change occurs at least in part as a result of environmentally-induced damage to the at least one conductive element.

In accordance with another embodiment of the present disclosure, an information handling system may include a processor, a memory communicatively coupled to the processor, and a circuit board communicatively coupled to the processor. The circuit board may include a test module comprising at least one conductive element. The circuit board may further include a detection module operably coupled to the test module, the detection module operable to detect a change in at least one electrical property associated with the at least one conductive element, wherein the change occurs at least in part as a result of environmentally-induced damage to the at least one conductive element.

In a further embodiment of the present disclosure, a method for detection of environmentally-induced damage of conductive elements in a circuit board is provided. The method may include disposing a test module disposed in the circuit board, the test module comprising at least one conductive element. The method may further include detecting a change in at least one electrical property associated with the at least one conductive element, wherein the change occurs at least in part as a result of environmentally-induced damage to the at least one conductive element.

Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example circuit board depicting environmentally-induced damage of conductive elements, in accordance with the teachings of the present disclosure;

FIG. 2A illustrates a block diagram of an example system for the detection of environmentally-induced damage of conductive elements in a circuit board, in accordance with certain embodiments of the present disclosure;

FIG. 2B illustrates a test module for use in the system of FIG. 2A, in accordance with certain embodiments of the present disclosure;

FIG. 2C illustrates a block diagram of the system of FIG. 2A, in accordance with certain embodiments of the present invention;

FIG. 2D illustrates a circuit diagram of the system depicted in FIG. 2C, in accordance with certain embodiments of the present invention;

FIG. 2E illustrates another block diagram of the system of FIG. 2A, in accordance with certain embodiments of the present invention;

FIG. 2F illustrates detailed circuit diagram of the block diagram depicted in FIG. 2E, in accordance with certain embodiments of the present invention; and

FIG. 3 illustrates a flow chart of a method for the detection of environmentally-induced damage of conductive elements in a circuit board, in accordance with the teachings of the present disclosure.

### DETAILED DESCRIPTION

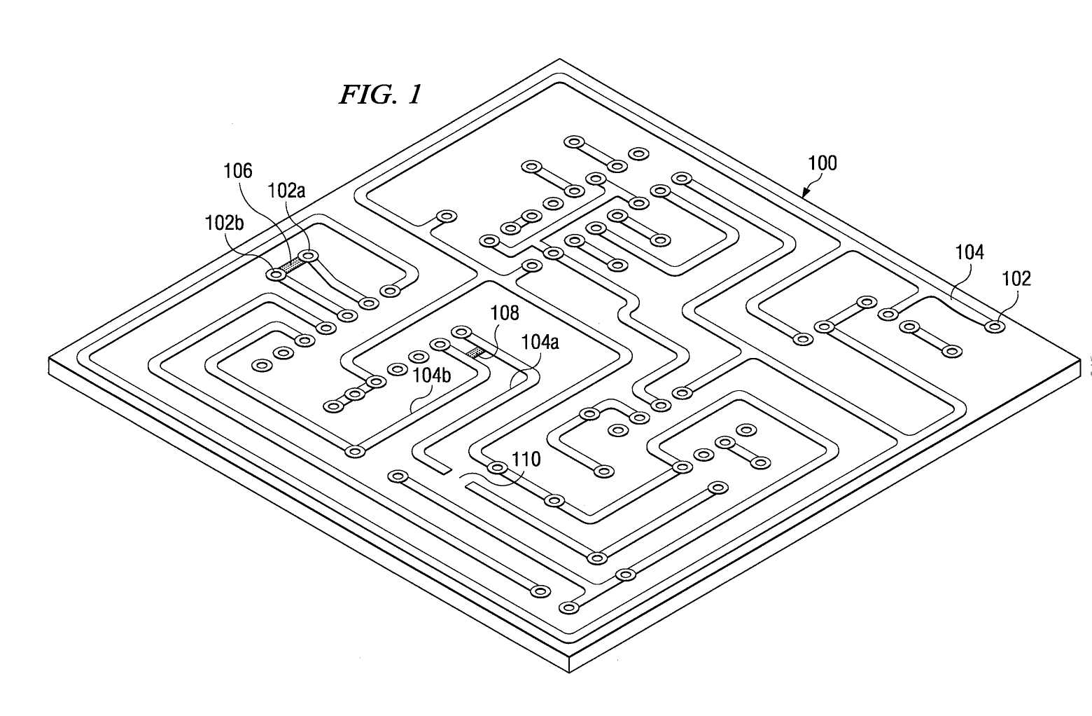

Preferred embodiments and their advantages are best understood by reference to FIGS. 1 through 3, wherein like numbers are used to indicate like and corresponding parts.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

As discussed above, an information handling system may include one or more circuit boards operable to mechanically support and electrically connect electronic components making up the information handling system (e.g., packaged integrated circuits). Circuit boards may be used as part of motherboards, memories, storage devices, storage device controllers, peripherals, peripheral cards, network interface cards, and/or other electronic components. As used herein, the term “circuit board” includes printed circuit boards (PCBs), printed wiring boards (PWBs), etched wiring boards, and/or any other board or similar physical structure operable to mechanically support and electrically connect electronic components.

FIG. 1 illustrates an example circuit board 100 depicting environmentally-induced damage of certain conductive elements. As depicted in FIG. 1, circuit board 100 may include a plurality of pads 102 and traces 104. Pads 102 may comprise a conductive material and may be formed on a surface of circuit board 100. Further, each pad 102 may be operable to receive a pin of an electronic component (e.g., a packaged integrated circuit) and provide electrical connectivity between the pin and one or more traces 104. Traces 104 may comprise a conductive material and may be formed on a surface of circuit board 100, or in a layer of circuit board 100 not visible from the surface thereof. Further, each trace 104 may be operable to provide conductive pathways between electronic components mounted to pads 102. As used herein, the term “conductive element” may refer to pads 102, traces 104, and/or any other element disposed on, in, and/or within circuit board 100 that is operable to provide an electrically conductive pathway (e.g., vias). The various pads 102, traces 104, and vias may comprise silver, copper, aluminum, lead, nickel, other metals, metal alloys, and/or any other conductive material that may readily conduct electrical current.

Although FIG. 1 depicts conductive elements 102, 104 on the top surface of circuit board 100, it is understood that conductive elements 102 and 104 may also be disposed on the bottom surface of circuit board 100. In addition, circuit board 100 may comprise a plurality of conductive layers separated and supported by layers of insulating material laminated together, and traces 104 may be disposed on and/or in any of such conductive layers. Connectivity between conductive elements disposed on and/or in various layers of circuit board 100 may be provided by conductive vias.

Due to exposure, conductive elements 102 and 104 may experience environmentally-induced damage. For example, airborne substances, materials and chemicals may come into contact with conductive elements 102 and/or 104 and lead to oxidation, tarnishing, corrosion, decomposition and/or other damage to conductive elements 102 and/or 104. Other environmental conditions, e.g., heat or humidity, may also contribute environmentally-induced damage. Further, in certain applications, environmentally-induced damage may be caused by electromigration and/or similar phenomena, wherein portions of conductive material may be transported by the gradual movements of ions in a conductive elements 102 and/or 104 due to momentum transfer between conducting electrons and diffusing metal atoms.

Environmentally-induced damage to conductive elements 102 and/or 104 may contribute to malfunction and/or inoperability of circuit board 100. For example, environmentally-induced damage may cause certain conductive elements 102 and/or 104 designed to be electrically isolated from another (e.g., pads 102a and 102b, and traces 104a and 104b) to develop leakage currents between the conductive elements that may lead to malfunction and/or inoperability. As another example, environmentally-induced damage may also cause conductive elements 102 and/or 104 that are designed to be electrically isolated from one other to form a “bridge” or a “short” (e.g., short 106 between pads 102a and 102b, or short 108 between traces 104a and 104b, as shown in FIG. 1), that may also lead to malfunction and/or inoperability of circuit board 100. In other instances, environmentally-induced damage may cause a “break” in one or more conductive elements 102 and/or 104, thereby creating an “open” (for example, open 110 on trace 104a) that may lead to malfunction and/or inoperability.

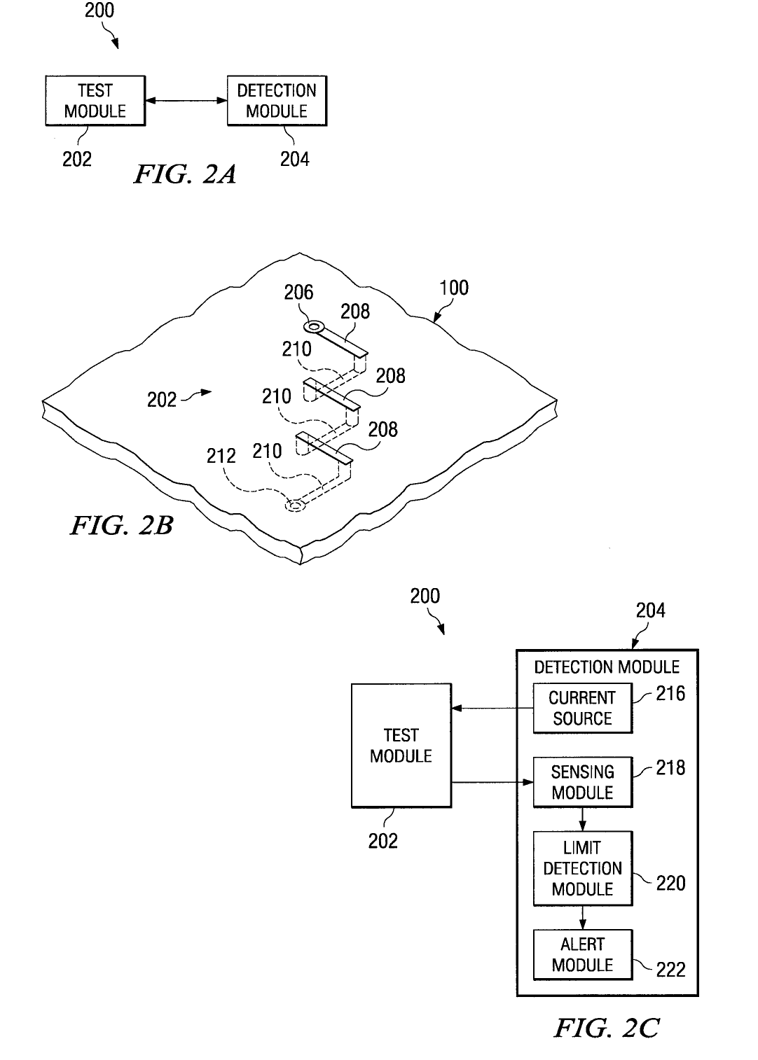

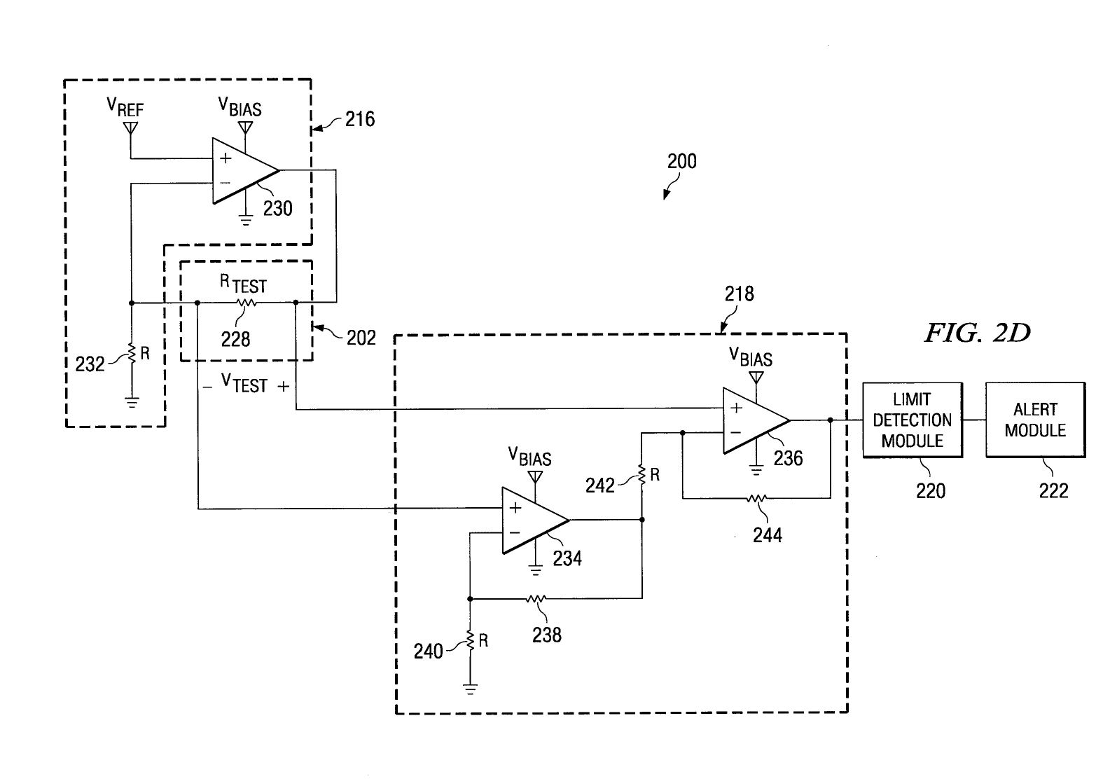

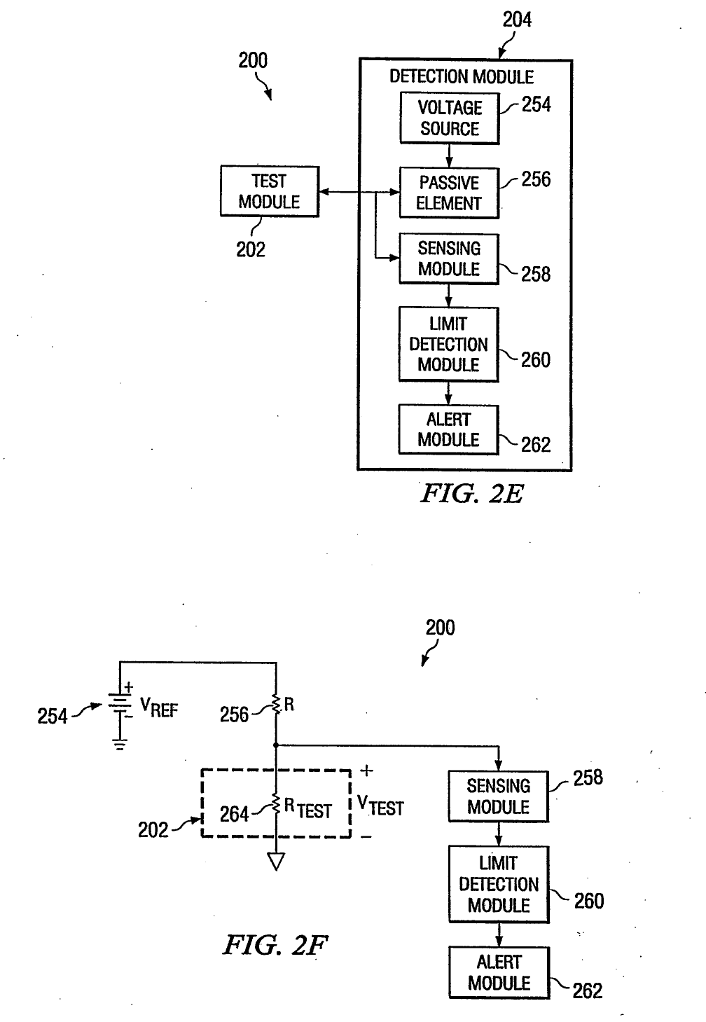

FIG. 2A illustrates a block diagram of an example system 200 for the detection of environmentally-induced damage of conductive elements 102 and 104 in a circuit board 100, in accordance with the teachings of the present disclosure. As depicted in FIG. 2A, system 200 may comprise test module 202 and detection module 204 operably connected to test module 202. Test module 202 may be disposed in a circuit board, e.g., circuit board 100, and may comprise at least one conductive element (e.g., at least one pad 102 and/or trace 104). Detection module 204 may be operable to detect a change in at least one electrical property associated with the one or more conductive elements of test module 202. One or more electrical properties of a conductive element 102 and/or 104 may change as a result of environmentally-induced damage. For example, environmentally-induced damage may cause a change in the resistance, capacitance, inductance, and/or other electrical property of a conductive element 102 and/or 104. Thus, by detecting a change in one or more electrical properties of a conductive element 102 and/or 104, detection module 204 may, in effect, detect the presence of environmentally-induced damage.

In certain embodiments, test module 202 and/or detection module 204 may be formed in, on and/or within an otherwise usable circuit board. For example, test module 202 and/or detection module 204 may be formed in, on and/or within a circuit board operable as part of a motherboard, storage device, storage device controller, peripheral, peripheral card, network interface card, and/or other electronic component.

FIG. 2B illustrates a test module 202 for use in system 200, in accordance with certain embodiments of the present disclosure. As depicted in FIG. 2B, test module 202 may be disposed in a circuit board, such as circuit board 100, and may comprise one or more pads 206 and 212, and one or more traces 208 and 210. In the depicted embodiment, pad 206 and traces 208 may be disposed on the top surface of circuit board 100, and pad 212 and traces 210 may be disposed on the bottom surface of pad 100 (as indicated by dashed lines in FIG. 2B). Traces 208 and 210 may be electrically coupled by vias formed in circuit board 100. Pads 206 and 212 may be similar in design and/or functionality as pads 102 depicted in FIG. 1, and traces 206 and 208 may be similar in design and/or functionality as traces 104 depicted in FIG. 1.

In operation, conductive elements 206, 208, 210, and/or 212 may experience environmentally-induced damage that may change one or more electrical properties of conductive elements 206, 208, 210, and/or 212. Accordingly, by detecting the change of one or more of the electrical properties of test module 202, detection module 204 may, in effect, detect the presence of environmentally-induced damage to conductive elements 206, 208, 210, and/or 212.

By disposing the various conductive elements 206, 208, 210 and 212 on both surfaces of circuit board 100 as depicted in FIG. 2B, each conductive element 206, 208, 210, and 212 may be advantageously exposed to one or more environmental conditions that may cause environmentally-induced effects. For example, if circuit board 100 were to be used in a caustic atmosphere (as is often the case in many manufacturing and industrial applications), environmentally-induced effects may be more prevalent in conductive elements disposed on the surfaces of circuit board 100, as compared to conductive elements disposed within internal layers of circuit board 100. Accordingly, a test module 202 with conductive elements 206-212 disposed on the surfaces of circuit board 100 may provide greater sensitivity than a test module with one or more conductive elements disposed within internal conductive layers of circuit board 100.

However, although FIG. 2B depicts test module 202 with conductive elements 206-212 disposed on the surfaces of circuit board 100, it is understood that test module 202 may include conductive elements disposed on any conductive layer of circuit board 100. In addition, although FIG. 2B depicts test module 202 with conductive elements 206-212 disposed on both surfaces of circuit board 100, it is understood that test module 202 may include conductive elements disposed on only one surface of circuit board 100.

In certain embodiments, the geometry and/or location of test module 202 may be selected to increase the sensitivity of test module 202. For example, test module 202 may be placed on portions of circuit board 100 near airflow inlets and/or outlets of an information handling system, thus potentially increasing the exposure of test module 202 to conditions that may cause environmentally-induced damage.

In certain embodiments of the present disclosure, test module 202 and detection module 204 may be continuously monitored during use of circuit board 100 (e.g., during use of circuit board 100 in an information handling system and/or use by an end-user of circuit board 100). Thus, the systems and methods discussed herein may allow use of circuit board 100 for its intended purpose while also continuously monitoring test module 202 and detection module 204 for the presence of detected environmentally-induced damage.

FIG. 2C illustrates a block diagram of the system of FIG. 2A, in accordance with certain embodiments of the present invention. As depicted in FIG. 2C, detection module 204 may include a current source 216, a sensing module 218, a limit detection module 220, and an alert module 222. Current source 216 may be coupled to test module 202 and may be operable to induce an electrical potential across test module 202. The electrical potential induced across test module 202 may be indicative of at least one electrical property of one or more conductive elements of test module 202. Sensing module 218 may be coupled to test module 202, and may be operable to detect the induced electrical potential. Limit detection module 220 may be coupled to sensing module 218 and may be operable to determine whether the induced electrical potential is within a predetermined acceptable range. The predetermined acceptable range may have one or more limits that correspond to allowable, acceptable, safe, or recommended limits or thresholds of environmentally-induced damage to conductive elements of test module 202. In certain embodiments, the one or more limits of the predetermined acceptable range may be based at least in part on experimental data. In the same or alternative embodiments, the one or more limits of the predetermined acceptable range may be pre-programmed and/or otherwise set by a manufacturer and/or reseller of circuit board 100. In certain embodiments, the one or more limits of the predetermined acceptable range may be set in response to user input.

Alert module 222 may be may be coupled to limit detection module 220 and may be operable to signal that the induced electrical potential is not within the predetermined acceptable range.

In operation, current source 216 may induce an electrical potential across test module 202, which may be detected by sensing module 218. Test module 202 may experience environmentally-induced damage, and, as a result, one or more electrical properties of one or more conductive elements 202-212 of test module 202 may change. The change in electrical properties may cause a change in the induced electrical potential across test module 202 that may be sensed by sensing module 218. Limit detection module 220 may detect if such change causes the electrical potential to stray from a predetermined acceptable range, and alert module 222 may signal that the electrical potential is not within the predetermined acceptable range, thus indicating that a particular level of environmentally-induced damage has occurred in test module 202.

FIG. 2D illustrates an example circuit diagram of system 200 depicted in FIG. 2C, in accordance with certain embodiments of the present invention. As depicted in FIG. 2D, test module 202 may in some embodiments be modeled as an equivalent resistor 228 with resistance R_{TEST}, representing the resistance of test module 202.

As shown in FIG. 2D, current source 216 may in some embodiments be implemented using an operational amplifier 230 with a positive terminal input voltage of V_{REF} and resistor 232 with resistance R. In operation, this configuration of current source 216 may induce a constant current equal to V_{REF}/R through test module 202. This current may induce a corresponding electrical potential, V_{TEST}, across test module 202, such that V_{TEST}=V_{REF}R_{TEST}/R.

Sensing module 218 may in some embodiments be implemented using the differential amplifier defined by operational amplifiers 234 and 236 and resistors 238, 240, 242 and 244. In operation, test module 202 may experience environmentally-induced damage, and, as a result, R_{TEST} and/or one or more other electrical properties of one or more conductive elements of test module 202 may change. The change in R_{TEST} may cause a change in the induced electrical potential V_{TEST} across test module 202 that may be sensed by sensing module 218.

The electrical potential V_{TEST} sensed by the differential amplifier of sensing module 218 may be output to limit detection module 220. As discussed above, limit detection module 220 may detect if the change in R_{TEST} has caused V_{TEST} to stray from a predetermined acceptable range, and alert module 222 may signal that V_{TEST} is not within the predetermined acceptable range, which may indicate that a particular level of environmentally-induced damage has occurred in test module 202.

Although FIG. 2D depicts a particular implementation of current source 216, it is understood that current source 216 may be of any design and may include any system, apparatus, or device operable to deliver or absorb electrical current, in accordance with the present disclosure. In addition, although FIG. 2D indicates that current source 216 may be implemented in hardware, it is understood that current source 216 may be implemented in hardware, software, firmware, or any combination thereof.

Similarly, although FIG. 2D depicts a particular implementation of sensing module 218, it is understood that sensing module 218 may be of any design and may include any system, apparatus, or device operable measure or detect the electrical potential across test module 202, in accordance with the present disclosure. Furthermore, although FIG. 2D indicates that sensing module 218 may be implemented in hardware, it is understood that sensing module 218 may be implemented in hardware, software, firmware, or any combination thereof.

Although neither of FIGS. 2C and 2D depict a particular implementation of limit detection module 220, it is understood that limit detection module 220 may comprise one or more comparators, and/or any system, apparatus, and/or device operable to compare the electrical potential sensed by sensing module 218 to one or more limits of a predetermined acceptable range, in accordance with the present disclosure. Limit detection module 220 may be implemented in hardware, software, firmware, or any combination thereof.

Similarly, although neither of FIGS. 2C and 2D depict a particular implementation of alert module 222, it is understood that alert module 222 may comprise any system, apparatus, and/or device operable to issue a signal that the electrical potential sensed by sensing module 218 has strayed from the predetermined acceptable range. In certain embodiments, the signal may comprise any visual, auditory, and/or other human-sensible signal. In the same or alternative embodiments, alert module 222 may cause a warning message to be displayed on a display device of an information handling system associated with a particular circuit board. In the same or alternative embodiments, alert module 222 may cause a text or data entry in a file, e.g., a log file, embodied in a computer-readable medium associated with an information handling system. In addition, alert module 222 may be implemented in hardware, software, firmware, or any combination thereof.

FIG. 2E illustrates a block diagram of system 200 of FIG. 2A, in accordance with certain embodiments of the present invention. As depicted in FIG. 2E, detection module 204 may include a voltage source 254, a passive element 256, a sensing module 258, a limit detection module 260, and an alert module 262. Voltage source 254 may be operably coupled to test module 202 and may be operable to induce an electrical potential across test module 202. The electrical potential induced across test module 202 may be indicative of at least one electrical property of one or more conductive elements of test module 202. Passive element 256 may be operably coupled to test module 202, and may affect the electrical potential induced across test module 202.

Sensing module 258 may be coupled to test module 202, and may be operable to detect the induced electrical potential. Sensing module 258 may be similar in design and/or functionality to sensing module 218 of FIGS. 2B and 2C. Limit detection module 260 may be coupled to sensing module 258 and may be operable to determine whether the induced electrical potential is within a predetermined acceptable range. Limit detection module 260 may be similar in design and/or functionality to limit detection module 220 of FIGS. 2B and 2C. Alert module 262 may be may be coupled to limit detection module 260 and may be operable to signal that the induced electrical potential is not within the predetermined acceptable range. Alert module 260 may be similar in design and/or functionality to limit detection module 260 of FIGS. 2B and 2C.

In operation, voltage source 254 may induce an electrical potential across test module 202, which may be detected by sensing module 258. Test module 202 may experience environmentally-induced damage, and, as a result, one or more electrical properties of one or more conductive elements 206-212 of test module 202 may change. The change in electrical properties may cause a change in the induced electrical potential across test module 202 that may be sensed by sensing module 258. Limit detection module 260 may detect if such change causes the electrical potential to stray from a predetermined acceptable range, and alert module 262 may signal that the electrical potential is not within the predetermined acceptable range, thus indicating that a particular level of environmentally-induced damage has occurred in test module 202.

FIG. 2F illustrates an example circuit diagram of the block diagram of system 200 depicted in FIG. 2E, in accordance with certain embodiments of the present invention. As depicted in FIG. 2F, test module 202 may in some embodiments be modeled as an equivalent resistor 264 with resistance R_{TEST}, representing the resistance of test module 202.

As shown in FIG. 2F, passive element 256 is implemented as a resistor with resistance R. Test module 202 and passive element 256 may create a voltage divider, such that electrical potential V_{TEST} induced by voltage source 254 may be represented by the equation V_{TEST}=V_{REF}R_{TEST}/(R_{TEST}+R). In operation, test module 202 may experience environmentally-induced damage, and, as a result, R_{TEST} or one or more other electrical properties of one or more conductive elements of test module 202 may change. The change in R_{TEST} may cause a change in the induced electrical potential V_{TEST} across test module 202 that may be sensed by sensing module 258.

The electrical potential V_{TEST} sensed by the differential amplifier of sensing module 258 may be output to limit detection module 260. As discussed above, limit detection module 260 may detect if the change in R_{TEST} has caused V_{TEST} to stray from a predetermined acceptable range, and alert module 262 may signal that V_{TEST} is not within the predetermined acceptable range, which may indicate that a particular level of environmentally-induced damage has occurred in test module 262.

Although the implementation depicted in FIG. 2F shows passive element 256 coupled to positive terminal of voltage source 254, and test module 202 coupled to passive element 256 and a ground potential, it is understood that the placement of passive element 256 and test module may be reversed in the implementation shown in FIG. 2F. In addition, although FIG. 2F indicates that an electrical potential across test module 202 is sensed to detect environmentally-induced damage of test module 202, it is understood that the electrical potential across passive element 256 may also be sensed to detect environmentally-induced damage of test module 202. In such an implementation, the electrical potential induced across passive element 256 by voltage source 254 may be equal to V_{REF}R/(R_{TEST}+R) In operation, test module 202 may experience environmentally-induced damage, and, as a result, R_{TEST} or one or more other electrical properties of one or more conductive elements of test module 202 may change. The change in R_{TEST} may cause a change in the induced electrical potential across passive element 256 that may be sensed by sensing module 258.

Although neither of FIG. 2E or 2F depict a particular implementation of voltage source 254, it is understood that voltage source 254 may comprise any system, apparatus, and/or device operable to produce an electromotive force between its terminals and induce an electrical potential across test module 202, in accordance with the present disclosure. Voltage source 220 may be implemented in hardware, software, firmware, or any combination thereof.

In addition, although FIG. 2F depicts a particular implementation of passive element 256, it is understood that current source 256 may be of any design and may include any passive circuit element, including without limitation resistors, capacitors, inductors, or any combination thereof.

Similarly, although neither of FIG. 2E or 2F depict a particular implementation of sensing module 258, it is understood that sensing module 258 may be of any design and may include any system, apparatus, or device operable measure or detect the electrical potential across test module 202, in accordance with the present disclosure. Sensing module 258 may be implemented in hardware, software, firmware, or any combination thereof.

Moreover, although neither of FIG. 2E or 2F depict a particular implementation of limit detection module 260, it is understood that limit detection module 260 may comprise one or more comparators, and/or any system, apparatus, and/or device operable to compare the electrical potential sensed by sensing module 258 to one or more limits of a predetermined acceptable range, in accordance with the present disclosure. Limit detection module 260 may be implemented in hardware, software, firmware, or any combination thereof.

Similarly, although neither of FIG. 2E or 2F depict a particular implementation of alert module 262, it is understood that alert module 262 may comprise any system, apparatus, and/or device operable to issue a signal that the electrical potential sensed by sensing module 258 has strayed from the predetermined acceptable range. In certain embodiments, the signal may comprise any visual, auditory, and/or other human-sensible signal. In the same or alternative embodiments, alert module 262 may cause a warning message to be displayed on a display device of an information handling system associated with a particular circuit board. In the same or alternative embodiments, alert module 262 may cause a text or data entry in a file, e.g., a log file, embodied in a computer-readable medium associated with an information handling system. In addition, alert module 262 may be implemented in hardware, software, firmware, or any combination thereof.

Although the implementations depicted in FIGS. 2D and 2F are operable to detect a change in resistance of one or more conductive elements of test module 202 in order to indicate the occurrence of environmentally-induced damage, it is understood that the methods and systems disclosed herein may be operable to detect a change in any electrical property of one or more conductive elements of test module 202, including without limitation resistance, capacitance, inductance, and/or any combination thereof.

In certain embodiments of the present disclosure, certain outputs of various components of system 200 may be transmitted to an information handling system general purpose input/output (GPIO). For example, in some embodiments, the output of sensing module 218 depicted in FIGS. 2C and 2D may be transmitted to a GPIO of an information handling system. The transmitted signal may then be further transmitted to a limit detection module 220 disposed within the information handling system and implemented in hardware, software, firmware or any combination thereof. In other embodiments, the output of limit detection module 220 depicted in FIGS. 2C and 2D may be transmitted to a GPIO of an information handling system. The transmitted signal may further be transmitted to an alert module 222 disposed within the information handling system and implemented in hardware, software, firmware or any combination thereof.

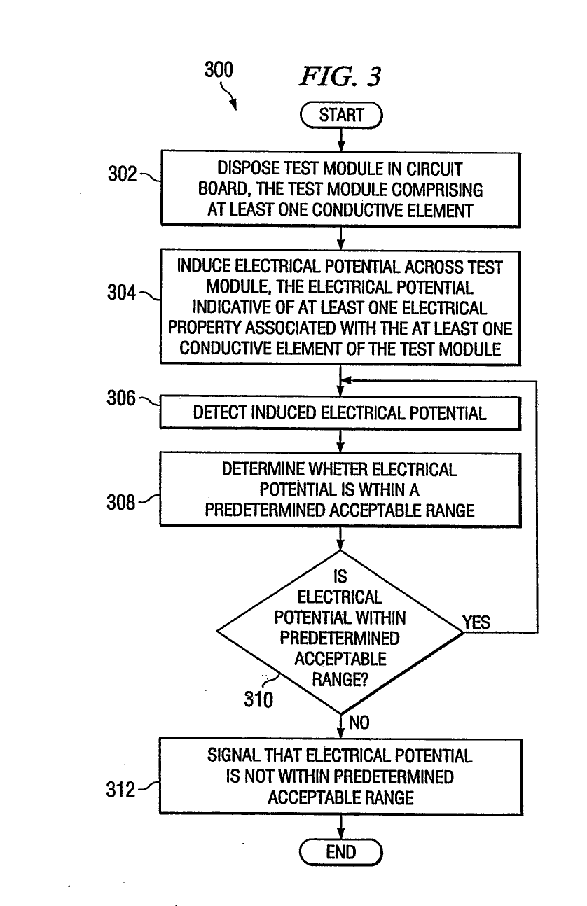

FIG. 3 illustrates a flow chart of a method 300 for the detection of environmentally-induced damage of conductive elements 206-212 in a circuit board 100, in accordance with the teachings of the present disclosure. In one embodiment, method 300 includes disposing test module 202 in a circuit board 100, the test module comprising at least one conductive element 206-212. A current or voltage source (e.g. current source 216 or voltage source 254) may induce an electrical potential across test module 202. A sensing module (e.g., 218 or 258) may detect the induced electrical potential and a limit detection module (e.g., 220 or 260) may determine whether the electrical potential is within a predetermined acceptable range. If the electrical potential is not within the predetermined acceptable range, an alert module (e.g. 222 or 262) may signal that the electrical potential is not within the predetermined acceptable range, which may indicate a degree of environmentally-induced damage of at least one of the conductive elements 206-212 of test module 202.

According to one embodiment, method 300 preferably begins at step 302. As noted above, teachings of the present disclosure may be implemented in a variety of configurations of system 100. As such, the preferred initialization point for method 300 and the order of the steps 302-312 of method 300 may depend on the implementation chosen.

At step 302, test module 202 may be disposed in circuit board 100, using any acceptable process in accordance with the present disclosure. At step 304, a current or voltage source (e.g. current source 216 or voltage source 256) may induce an electrical potential across test module 202. The induced electrical potential may be indicative of at least one electrical property associated with the at least one conductive element 206-212 of the test module 202. At step 306, a sensing module (e.g., 218 or 258) may detect the induced electrical potential across module 202, and at step 308, a limit detection module (e.g., 220 or 260) may determine whether the electrical potential if within a predetermined acceptable range.

At step 310, if the electrical potential across test module 202 is within the predetermined acceptable range, method 300 may proceed again to step 306, in order to continuously monitor whether the electrical potential remains within the predetermined acceptable range. Otherwise, if the electrical potential across test module 202 is not within the predetermined acceptable range, method 300 may proceed to step 312. At step 312, an alert module (e.g., 222 or 262) may signal that the electrical potential is not within the predetermined acceptable range. After execution of step 312, method 300 may end as depicted in FIG. 3, or, in certain embodiments, method 300 may proceed again to step 306, in order to continuously monitor whether the electrical potential remains outside of the predetermined acceptable range.

Although the present disclosure has been described in detail, it should be understood that various changes, substitutions, and alterations can be made hereto without departing from the spirit and the scope of the invention as defined by the appended claims.

1. A system for detection of environmentally-induced damage of conductive elements in a circuit board, comprising:
a test module disposed in the circuit board, the test module comprising at least one conductive element; and
a detection module operably coupled to the test module, the detection module operable to detect a change in at least one electrical property associated with the at least one conductive element, wherein the change occurs at least in part as a result of environmentally-induced damage to the at least one conductive element.

2. A system according to claim 1, wherein the at least one electrical property comprises a resistance of at the least one conductive element.

3. A system according to claim 1, wherein the detection module comprises:
a current source operably coupled to the test module, the current source operable to induce an electrical potential across the test module, the electrical potential indicative of the at least one electrical property; and
a sensing module operably coupled to the test module, the sensing module operable to detect the induced electrical potential.

4. A system according to claim 3, wherein the detection module further comprises a limit detection module operably coupled to the sensing module, the limit detection module operable to determine whether the electrical potential is within a predetermined acceptable range.

5. A system according to claim 4, wherein the detection module further comprises an alert module operably coupled to the limit detection module, the alert module operable to signal that the electrical potential is not within the predetermined acceptable range.

6. A system according to claim 1, wherein the detection module comprises:
a passive element operably coupled to the test module; and
a voltage source operably coupled to at least one of the passive element and the test module;
wherein the passive element and test module are configured such that a change in the at least one electrical property induces a change in an electrical potential across at least one of the passive element and the test module.

7. A system according to claim 1, wherein the test module comprises at least one of a pad and a trace.

8. A information handling system comprising:
a processor;
a memory communicatively coupled to the processor; and
a circuit board communicatively coupled to the processor, the circuit board comprising:
a test module comprising at least one conductive element; and
a detection module operably coupled to the test module, the detection module operable to detect a change in at least one electrical property associated with the at least one conductive element, wherein the change occurs at least in part as a result of environmentally-induced damage to the at least one conductive element.

9. An information handling system according to claim 8, wherein the at least one electrical property comprises a resistance of at the least one conductive element.

10. An information handling system according to claim 8, wherein the detection module comprises:
a current source operably coupled to the test module, the current source operable to induce an electrical potential across the test module, the electrical potential indicative of the at least one electrical property; and
a sensing module operably coupled to the test module, the sensing module operable to detect the induced electrical potential.

11. An information handling system according to claim 10, wherein the detection module further comprises a limit detection module operably coupled to the sensing module, the limit detection module operable to determine whether the electrical potential is within a predetermined acceptable range.

12. An information handling system according to claim 11, wherein the detection module further comprises an alert module operably coupled to the limit detection module, the alert module operable to signal that the electrical potential is not within the predetermined acceptable range.

13. An information handling system according to claim 8, wherein the detection module comprises:
a passive element operably coupled to the test module; and
a voltage source operably coupled to at least one of the passive and the test module;
wherein the passive element and test module are configured such that a change in the at least one electrical property induces a change in an electrical potential across at least one of the passive element and the test module.

14. An information handling system according to claim 8, wherein the test module comprises at least one of a pad and a trace.

15. A method for detection of environmentally-induced damage of conductive elements in a circuit board comprising:
disposing a test module in the circuit board, the test module comprising at least one conductive element; and
detecting a change in at least one electrical property associated with the at least one conductive element, wherein the change occurs at least in part as a result of environmentally-induced damage to the at least one conductive element.

16. A method according to claim 15, wherein the at least one electrical property comprises a resistance of at the least one conductive element.

17. A method according to claim 15, wherein detecting the change in the at least one electrical property comprises:
inducing an electrical potential across the test module, the electrical potential indicative of the at least one electrical property; and
detecting the induced electrical potential.

18. A method according to claim 17, wherein detecting the change in the at least one electrical property further comprises determining whether the electrical potential is within a predetermined acceptable range.

19. A method according to claim 18, further comprising signaling that the electrical potential is not within the predetermined acceptable range.

20. A method according to claim 15, wherein the test module comprises at least one of a pad and a trace.
